(19) United States
(12) Patent Application Publication
(10) Pub. No.: US 2021/0407049 A1
(43) Pub. Date: Dec. 30, 2021

(54) GENERATING A HOMOGENIZATION FIELD FOR MAGNETIC RESONANCE IMAGE DATA

(71) Applicant: Siemens Healthcare GmbH, Erlangen (DE)

(72) Inventor: Marcel Dominik Nickel, Herzogenaurach (DE)

(73) Assignee: Siemens Healthcare GmbH, Erlangen (DE)

(21) Appl. No.: 17/363,343

(22) Filed: Jun. 30, 2021

(30) Foreign Application Priority Data
Jun. 30, 2020 (DE) 102020208186.7

(51) Int. Cl. G06T 5/00

(52) U.S. Cl. CPC G06T 5/002; G06T 2207/10088

(57) ABSTRACT

A method for generating a homogenization field for image data having image elements imaging an examination region may include: selecting a first image element comprising at least two first intensity values for a first positional value; smoothing image data surrounding the first image element in respect of the at least one spatial dimension to generate first smoothed image data; applying a robust estimation method to the first smoothed image data in respect of the statistical dimension to generate robustly estimated image data; and determining the homogenization field for the first positional value based on the robustly estimated image data. The examination region may be defined by positional values in at least one spatial dimension. The one image element in each case for one positional value in each case in the spatial dimension may include at least two intensity values in a statistical dimension.

### CROSS REFERENCE TO RELATED APPLICATIONS

This patent application claims priority to German Patent Application No. 10 2020 208 186.7, filed Jun. 30, 2020, which is incorporated herein by reference in its entirety.

### BACKGROUND

### Field

The disclosure relates to a method, an image processing system, a computer program product and an electronically readable data medium for generating a homogenization field for magnetic resonance image data.

### Related Art

In a magnetic resonance device, the body of an examination subject that is to be examined, in particular the body of a patient, is typically exposed to a relatively high main magnetic field, of 1.5 or 3 or 7 tesla for example, with the aid of a main magnet. In addition, gradient pulses are applied with the aid of a gradient coil unit. High-frequency radiofrequency pulses, for example excitation pulses, are then transmitted by means of suitable antenna facilities via a radiofrequency antenna unit, which results in the nuclear spins of certain atoms excited into resonance by means of said radiofrequency pulses being tipped through a defined flip angle relative to the magnetic field lines of the main magnet field. During the relaxation of the nuclear spins, radiofrequency signals, referred to as magnetic resonance signals (MR signals), are emitted, received by means of suitable radiofrequency antennas and then processed further. Finally, the desired image data, known as MR image data, can be reconstructed from the raw data acquired in the process. The region of the examination subject that is to be visualized is the examination region.

To perform a particular measurement, it is therefore necessary to transmit a specific magnetic resonance control sequence (MR control sequence), also referred to as a pulse sequence, which consists of a series of radiofrequency pulses, for example excitation pulses and refocusing pulses, as well as, fitted thereto, gradient pulses that are to be transmitted in a coordinated manner in different gradient axes along different spatial directions. Readout windows, aligned with respect to time to said pulses, are set which specify the time periods in which the induced MR signals are captured.

When a gradient pulse is transmitted, a magnetic field gradient, in particular a temporary magnetic field gradient, is generated in the examination region. When an excitation pulse is transmitted, a temporary RF field, also known as a B1 field or B1⁺ field, is generated in the examination region. Similarly, the radiofrequency antennas suitable for receiving the MR signals radiated from the examination subject have a spatial characteristic which is referred to as a B1 receive field or B1⁻ field. The B1 field and the B1 receive field can be influenced in different ways in the examination region due to the geometry of the examination subject and/or on account of a design of a component of the magnetic resonance device and be inhomogeneous in different ways. The same applies to the main magnetic field and/or magnetic field gradients. This can result in a tissue having different signal intensities, i.e. different intensity values, in image data, i.e. in the image data being corrupted. A homogenization field, known in the technical literature as a “bias field”, is a spatially resolved metric representative of smooth changes in signal intensity due to said effects and possible further influencing factors, such as motion, for example. Changes in signal intensity due to said effects and possible further influencing factors typically correspond to a local reduction in signal intensity, with the result that image data may be locally darker and/or may exhibit local extinctions. A homogenization field can quantify homogeneously locally varying signal intensities in image data. The image data can be homogenized with the aid of a homogenization field. A homogenization of magnetic resonance data may comprise a correction of a local variation in signal intensity, which local variation in signal intensity is not based on an anatomy and/or a pathology of the examination subject and/or of the examination region. A homogenization of magnetic resonance data may comprise a reduction in local changes in the signal intensity of the image data and/or a reduction in artifacts.

The spatial resolution of the examination region is defined by its size and the number of discrete image elements (pixels/voxels) contained therein at corresponding positional values. A positional value defines the position of the image element within the examination region. A positional value is typically a three-dimensional value and/or is defined by a tuple. The image data may have a number of intensity values for each positional value. This can be achieved by means of imaging scans with repetitions, i.e. an MR control sequence or specific sections of an MR control sequence is or are applied repeatedly and the corresponding MR signals are recorded. The repeatedly applied MR control sequence and/or specific sections of an MR control sequence for acquiring multiple intensity values for a positional value are preferably the same for each intensity value or differ by preferably no more than one sequence parameter, particularly preferably by no more than two sequence parameters. A sequence parameter may be for example an amplitude and/or a direction of a gradient pulse and/or of a radiofrequency pulse. The multiple intensity values for an image element can be combined, which leads to an increase in the signal-to-noise ratio, i.e. to an improvement in the quality of the image data. In particular a movement of the examination subject during and/or between the acquisitions of the multiple intensity values can lead to an inconsistency in the image data. This inconsistency can be corrected by determining a homogenization field and using the homogenization field for the homogenization of the individual intensity values and/or of the combined image data. An intensity value for a positional value is a metric for the signal intensity at the positional value. An intensity value is preferably based on reconstructed MR signals, that is to say on reconstructed raw data. The intensity value is dependent on the tissue of the examination subject at the positional value and the MR control sequence used for the acquisition of the image data.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows an image processor, in a schematic view, according to an exemplary embodiment.

FIG. 2 shows a flowchart of a method according to an exemplary embodiment.

FIG. 3 shows a flowchart of a method according to an exemplary embodiment.

FIG. 4 shows conventionally homogenized diffusion-weighted image data.

FIG. 5 shows a homogenization field according to an exemplary embodiments.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

The object underlying the disclosure is to disclose a method for generating a particularly robust and precise homogenization field.

In an exemplary embodiment, the inventive method for generating a homogenization field for image data comprising a plurality of image elements imaging an examination region of an examination subject, wherein the examination region is defined by positional values in at least one spatial dimension and one image element in each case from the plurality of image elements for one positional value in each case in the spatial dimension comprises at least two intensity values in a statistical dimension, provides the following method steps:
providing the image data,
selecting a first image element comprising at least two first intensity values for a first positional value,
generating first smoothed image data by smoothing the image data surrounding the first image element in respect of the at least one spatial dimension,
generating robustly estimated image data by applying a robust estimation method to the first smoothed image data in respect of the statistical dimension,
determining the homogenization field for the first positional value taking into account the robustly estimated image data.

In an exemplary embodiment, the image data is MR image data. The image data differs in the statistical dimension typically by the time points at which the at least two intensity values were acquired from the examination region, the time points preferably differing by less than one hour, particularly preferably by less than 10 minutes.

In an exemplary embodiment, the plurality of image elements is typically defined by the size of the examination region and the size of an individual image element. The number of image elements is typically greater than 100, preferably greater than 1000, particularly preferably greater than 10000. The positional values typically comprise values in two spatial directions, preferably in three spatial directions, perpendicular to one another. A spatial direction typically defines a spatial dimension.

In an exemplary embodiment, the image data comprises one intensity value in each case for each positional value and at least two statistical values in the statistical dimension. The image data for a statistical value is typically an image of the examination region, accordingly maps the examination region. The number of intensity values for each positional value corresponds to the number of images of the examination region and/or to the magnitude of the statistical dimension of the image data. Providing the image data may comprise an acquisition of the image data by activating a magnetic resonance device.

The image data surrounding the first image element, in particular the first positional value, is typically defined by its positional values having a defined maximum distance from the first positional value. The defined maximum distance may be defined by a norm. The defined maximum distance is typically less than ⅔, preferably less than ½, particularly preferably less than ⅓ of the maximum extension of the examination region in at least one spatial dimension. The defined maximum distance typically comprises less than 100, preferably less than 50, particularly preferably less than 20 positional values. The defined maximum distance may be less than 20 cm, preferably less than 14 cm, particularly preferably less than 10 cm. The image data surrounding the first image element may surround the first image element in a circular manner, the maximum distance thereof corresponding to the defined maximum distance from the first positional value. The image data surrounding the first image element typically defines a region surrounding the first image element, in particular a region around the first positional value. The image data surrounding the first image element is typically a subregion of the examination region.

In an exemplary embodiment, the image data surrounding the first image element is smoothed specifically for the first image element. The image data surrounding the first image element may be smoothed separately for each statistical value in the statistical dimension. The smoothing of the image data surrounding the first image element may for example comprise a forming of a mean value of the intensity values of the image data surrounding the first image element separately for each individual statistical value. The smoothing of the image data surrounding the first image element may comprise a statistical evaluation of the image elements surrounding the first image element. The smoothing may be embodied in such a way that exclusively image elements having at most a defined maximum distance from the first positional value are taken into account. The smoothing may be embodied in such a way that exclusively image elements in the region surrounding the first image element are taken into account. The smoothing of the image data surrounding the first image element may comprise an application of a filter, in particular a linear filter, to the image data surrounding the first image element for each individual statistical value.

In an exemplary embodiment, the first smoothed image data comprises a first smoothed intensity value for each individual statistical value. The statistical dimension of the first smoothed image data accordingly corresponds to the statistical dimension of the image data.

In an exemplary embodiment, the robust estimation method is a statistical method. For the first positional value, the robust estimation method is applied to the first smoothed intensity values in the statistical dimension and generates a first robust estimated value for the first positional value. The first robust estimated value is a statistical value representative of the at least two first intensity values taking into account the image data surrounding the first image element. The first robust estimated value is a statistical value representative of the first smoothed intensity values for the first positional value. The robust estimation method has a lower sensitivity with respect to individual deviations of the at least two intensity values. Typically, the image data has at least three, preferably at least four, particularly preferably at least five intensity values for each positional value in the statistical dimension. If a first intensity value of the multiple intensity values is affected by a signal extinction and/or some other artifact, due for example to movement of the examination subject, then said first intensity value is assigned a lower weighting in the robustly estimated image data due to the robust estimation method than the remaining first intensity values. This is advantageous compared to a linear estimation method because in this way individual intensity values deviating strongly from the mean value and/or median, i.e. corrupted intensity values, are less strongly weighted. The robust estimation method implies a selection of individual intensity values deviating strongly from the mean value and/or median, i.e. corrupted intensity values.

The homogenization field for the first positional value is determined as a function of the robustly estimated image data. The homogenization field may be a function dependent on robustly estimated image data. The spatial resolution and/or the spatial dimensions of the homogenization field typically correspond to the spatial resolution and/or the spatial dimensions of the image data. In an exemplary embodiment, the homogenization field is determined analogously to the first positional value for a plurality of positional values, particularly preferably for all positional values of the examination region.

Owing to the smoothing and the application of a robust estimation method, a homogenization field determined according to the disclosure is particularly good at taking into account spatially local signal extinctions with a low statistical component. If the image data for a first positional value has for example five intensity values in the statistical dimension, where one of the five intensity values has less than 60%, preferably less than 40%, particularly preferably less than 20% of the arithmetic mean of the five intensity values, then the effect of the smoothing is that the first positional value is taken into account not singularly, but in its local context. This enables in particular also spatial differences of the positional values relating to the statistical dimension, for example due to movement of the examination subject, to be averaged and/or compensated for particularly efficiently. The robust estimation method enables a weaker weighting of a singular signal extinction in the statistical dimension than in the case of an arithmetic averaging. The combination of a robust estimation method with a smoothing function accordingly enables a fitted weighting of singular local and singular statistical deviations of the intensity values. A homogenization field determined in such a way is accordingly particularly robust and precise, in particular also with regard to local signal extinctions caused as a result of motion in the case of small number of intensity values in the statistical dimension. Taking at least two intensity values into account for determining the homogenization field enables statistical fluctuations during the acquisition of MR signals to be compensated for. Using the robust estimation method enables a good estimation of an intensity value relevant to the first positional value while taking into account the surroundings of the first image element. This method enables efficient processing of a larger set of image data that has a statistical dimension in addition to the at least one spatial dimension. The use of a larger set of image data for determining a homogenization field enables the homogenization field to be determined in a more precise and more robust manner.

An embodiment of the method additionally comprises a homogenization of the image data by multiplying the homogenization field with the image data. Image data homogenized in this way is typically free of local signal extinctions. In particular signal extinctions due to motion can be effectively corrected.

An embodiment of the method provides that the homogenization field is determined taking into account a rule for a combination of the image data in the statistical dimension. The combination of the image data in the statistical dimension may also comprise a registration of the image data in the statistical dimension to one another. Typically, the image data in the statistical dimension is combined in such a way that the combined image data comprises precisely one combined intensity value for each positional value. The combined intensity value may correspond to the mean value of the intensity values for each positional value. Alternatively, each intensity value can, with appropriate weighting, contribute to the combined intensity value. If the image data is diffusion-weighted image data having a diffusion weighting factor b, the positional value is defined by x and the statistical dimension is defined by n=[1, . . . N], then the rule for combination of the intensity values I_{n,x}^{b} can be for example:

$${J}_{x}^{b} = {\sum }_{n = 1}^{N} {ω}_{n , x} {I}_{n , x}^{b}$$

where the weighting factor for each intensity value is given by

$${ω}_{n , x} = \frac{1}{N} \frac{{I}_{n , x}^{{b}^{*}}}{\vert {I}_{n , x}^{b} \vert}$$

Jₓ^{b} denotes the combined image data. The weighting factor may also correspond to the rule for combination of the intensity values.

The combination rule can be taken into account in the determination of the homogenization field. In particular, the weighting factor for each individual positional value can be taken into account. A weighting factor of said kind can indicate a signal extinction at the first positional value, as a result of which, when taking account of the weighting factor as combination rule, a very low signal intensity at the first positional value in the homogenization field is included with lower weighting than other signal intensities. If a homogenization field determined in this way is used for homogenization of the image data, then the image data will have a particularly small number of signal extinctions and artifacts.

An embodiment of the method additionally comprises a combination of the image data in the statistical dimension into combined image data and a homogenization of the combined image data for the first positional value by multiplication of the homogenization field for the first positional value with the combined image data for the first positional value. The homogenization field determined according to the disclosure can be used independently of a statistical value for all image data, preferably for the combined image data. By taking into account at least two intensity values for a positional value for the combination and homogenization it is possible to achieve a particularly high signal-to-noise ratio with a simultaneously good reduction in artifacts. The homogenization field determined according to the disclosure may alternatively be used for a homogenization of the image data for each statistical value individually.

An embodiment of the method provides that the robust estimation method comprises forming a quantile, in particular an empirical p-quantile. The quantile is preferably implemented as a 0.5 quantile, i.e. as a median. Particularly preferably, the robust estimation method comprises forming a p-quantile for a value for p greater than 0.5, for example greater than 0.6, preferably greater than 0.7, particularly preferably greater than 0.8. Values greater than 0.5 for p are advantageous in particular when the intensity values in the statistical dimension for the first positional value exhibit a particularly large fluctuation. The quantile in the statistical dimension enables a good and robust estimation of an intensity value relevant to the first positional value while taking into account the surroundings of the first image element, with individual statistical deviations of the first intensity values being less strongly weighted. This is particularly simple to implement and replicate.

An embodiment of the method provides that the smoothing of the image data comprises a convolution. In an exemplary embodiment, the smoothing of the image data comprises a spatial filter which can be described with the aid of a convolution.

Taking up the above example of the diffusion-weighted image data with intensity values I_{n,x}^{b}, the smoothing of the image data can be realized by

(G*Iₙ^{b})ₓ

where G is a linear filter, for example. G can be configured in such a way that the intensity values for each n in the spatial environment of the first positional value x are averaged. This smoothing is particularly simple to implement since in particular the size of the environment of the first positional value can be determined by G. G may also simply be replaced by other filters.

An embodiment of the method provides that the robust estimation method applied to the first smoothed image data comprises a determination of a proportion of corrupted intensity values at the at least two first intensity values in the statistical dimension, in particular taking into account the first smoothed image data surrounding the first positional value. One of the at least two first intensity values can be counted as corrupted if the corresponding intensity value lies below and/or above a threshold value. In an exemplary embodiment, the robust estimation method applied to the first smoothed image data comprises in addition a determination for a metric, i.e. for a strength, of the corruption of the intensity values in the statistical dimension, in particular taking into account the first smoothed image data surrounding the first positional value. The proportion is typically formed for each positional value. A corrupted intensity value is typically lower than an intensity value free of corruption. This embodiment enables locally corrupted intensity values, in particular local signal losses, to be taken into account particularly effectively, and as a result allows a particularly good determination of the homogenization field.

An embodiment of the method additionally comprises generating linearly estimated image data by application of a linear estimation method to the first smoothed image data in respect of the statistical dimension, the homogenization field for the first positional value being determined taking into account the linearly estimated image data. The linear estimation method applied to the first smoothed image data in respect of the statistical dimension may comprise a centering in terms of the statistical distribution. The linear estimation method applied to the first smoothed image data may be based on a centered distribution of the first intensity values in the statistical dimension. The linearly estimated image data typically comprises precisely one linearly estimated intensity value for a positional value. By additionally taking linearly estimated image data into consideration in the determination of the homogenization field it is also possible to take particularly effective account of minor statistical fluctuations.

An embodiment of the method provides that the linear estimation method comprises forming an arithmetic mean and/or forming a standard deviation. A weighted averaging may also be carried out instead of the arithmetic mean. An analogous embodiment for the homogenization field is advantageous in particular for the combination of the at least two intensity values in the statistical dimension for forming combined image data. If the linear estimation method comprises forming a standard deviation, then the expected value of a normal distribution can be determined. The arithmetic mean may correspond to a value of 0.5 of a cumulative distribution function of a centered distribution. Linearly estimated image data of said type can be determined particularly easily.

An embodiment of the method provides that the determination of the homogenization field for the first positional value comprises a ratio of the robustly estimated image data to the linearly estimated image data.

Taking up the above example of the diffusion-weighted image data, and if, for example, use is made of a median representative of a quantile within the scope of the robust estimation method and an arithmetic mean within the scope of the linear estimation method, then the homogenization field can be determined separately for each diffusion weighting b by

$${B}_{x}^{b} = \frac{m e d i a {{n}_{n} ( G * {I}_{n}^{b} )}_{x}}{m e a {{n}_{n} ( G * {I}_{n}^{b} )}_{x}}$$

Alternatively, the homogenization field may also be determined by

$${B}_{x}^{b} = \frac{m e d i a {{n}_{n} ( G * {I}_{n}^{b} )}_{x}}{{\sum }_{n} {{ω}_{n , x} ( G * {I}_{n}^{b} )}_{x}}$$

A homogenization field determined in this way indicates a proportion of corrupted image data in the image data. A homogenization of the image data on the basis of said homogenization field generates particularly consistent image data and is particularly good at correcting signal extinctions.

An embodiment of the method provides that the robustly estimated image data and/or the linearly estimated image data are modified by a regularizer. The regularizer for the robustly estimated image data and/or the linearly estimated image data typically corresponds to the noise in the image data. The regularizer for the robustly estimated image data may be equivalent to the regularizer for the linearly estimated image data. The regularizer for the robustly estimated image data may be different from the regularizer for the linearly estimated image data. The regularizer for the robustly estimated image data δ and/or the regularizer for the linearly estimated image data ε may be taken into account in the determination of the homogenization field as follows:

$${B}_{x}^{b} = \frac{δ + m e d i a {{n}_{n} ( G * {I}_{n}^{b} )}_{x}}{ɛ + m e a {{n}_{n} ( G * {I}_{n}^{b} )}_{x}}$$

$$or$$

$${B}_{x}^{b} = \frac{δ + m e d i a {{n}_{n} ( G * {I}_{n}^{b} )}_{x}}{ɛ + {Σ}_{n} {{ω}_{n , x} ( G * {I}_{n}^{b} )}_{x}}$$

The use of a regularizer enables noise to be taken into account in the determination of the homogenization field, as a result of which the latter can be determined more precisely.

An embodiment of the method provides that the image data is diffusion-weighted image data and the image data in the statistical dimension is different at least to some extent based on its diffusion direction.

In diffusion-weighted MR imaging, diffusion imaging, the diffusion motion of certain materials in the body tissue can be measured and visualized in a spatially resolved manner. The strength of the diffusion weighting is defined by a variable known as the diffusion weighting factor, also referred to as the b-value. The diffusion weighting is generated by the use of gradient pulses generating defined gradient moments. The direction of the applied gradient pulses can determine the diffusion direction.

Within the context of diffusion-weighted magnetic resonance imaging, multiple MR signals are typically acquired for each image element of the examination region for one b-value. Said multiple MR signals are typically combined in the course of the image processing into a value for each image element. This can lead to an increase in the signal-to-noise ratio.

The homogenization field is typically determined separately for each b-value. The image data typically comprises at least two intensity values for each positional value for each b-value. However, the two intensity values may differ from one another in terms of the diffusion direction. In an exemplary embodiment, the image data for each diffusion direction comprises at least two intensity values for one b-value. This leads to an increase in the set of data in the statistical dimension, thereby enabling the homogenization field to be generated on the basis of a larger set of image data, as a result of which the homogenization field can be determined particularly accurately also for each individual b-value.

The disclosure further relates to an image processing system having a homogenization unit comprising an input, an output, a selection unit, a smoothing unit, an estimation unit and a determination unit. The homogenization unit is embodied to perform an inventive method for generating a homogenization field.

Via the input, the homogenization unit can be provided with image data and/or a smoothing algorithm and/or an algorithm for an estimation method and/or a rule for a combination of the image data in the statistical dimension. Further functions, algorithms or parameters required in the method can be provided to the homogenization unit via the input. The homogenization field and/or further results of an embodiment of the inventive method can be provided via the output.

The selection unit is embodied to select a first image element of the image data. The smoothing unit is embodied to smooth the image data surrounding the first image element in the spatial dimension. The estimation unit is embodied to apply a robust estimation method to image data, in particular to first smoothed image data. The estimation unit may also be embodied to perform a linear estimation method. The determination unit is embodied to perform a determination of the homogenization field for the first positional value taking into account the robustly estimated image data. The input, the output, the selection unit, the smoothing unit, the estimation unit and/or the determination unit may be at least partially integrated in one another and/or be at least partially connected to one another. The homogenization unit may be integrated into a magnetic resonance device and/or into an image processing system. The homogenization unit may also be installed separately from a magnetic resonance device. The homogenization unit may be connected to a magnetic resonance device.

Embodiments of the inventive image processing system are realized analogously to the embodiments of the inventive method. The image processing system may comprise further control components which are necessary and/or advantageous for performing an inventive method. Computer programs and further software may be stored on a memory unit of the homogenization unit, thereby enabling the processor unit of the homogenization unit to control and/or execute a method processing sequence of an inventive method automatically.

An inventive computer program product can be loaded directly into a memory unit of a programmable homogenization unit and has program code means for performing an inventive method when the computer program product is executed in the homogenization unit. As a result, the inventive method can be performed quickly and in an identically repeatable and robust manner. The computer program product is configured in such a way that it is able to carry out the inventive method steps by means of the homogenization unit. In this case the homogenization unit must meet the respective requirements, such as a suitable random access memory, a suitable graphics card or a suitable logic unit, for example, so that the respective method steps can be carried out efficiently. The computer program product is stored for example on an electronically readable medium or is held resident on a network or server from where it can be loaded into the processor of a local homogenization unit that is directly connected to the image processing system or may be embodied as part of the image processing system. Control information of the computer program product may also be stored on an electronically readable data medium. The control information of the electronically readable data medium may be embodied in such a way that it performs an inventive method when the data medium is used in a homogenization unit of an image processing system. Examples of electronically readable data media are a DVD, a magnetic tape or a USB stick on which electronically readable control information, in particular software, is stored. When said control information (software) is read from the data medium and loaded into a control unit and/or homogenization unit of an image processing system, all inventive embodiment variants of the above-described methods can be performed.

The disclosure further relates to an electronically readable data medium on which there is stored a program which is provided for performing a method for generating a homogenization field for image data.

The advantages of the inventive image processing system, the inventive computer program product and the inventive electronically readable data medium substantially correspond to the advantages of the inventive method for generating a homogenization field for image data, which are explained in detail hereinabove. Features, advantages or alternative embodiments mentioned in this context may equally be applied also to the other claimed subject matters, and vice versa.

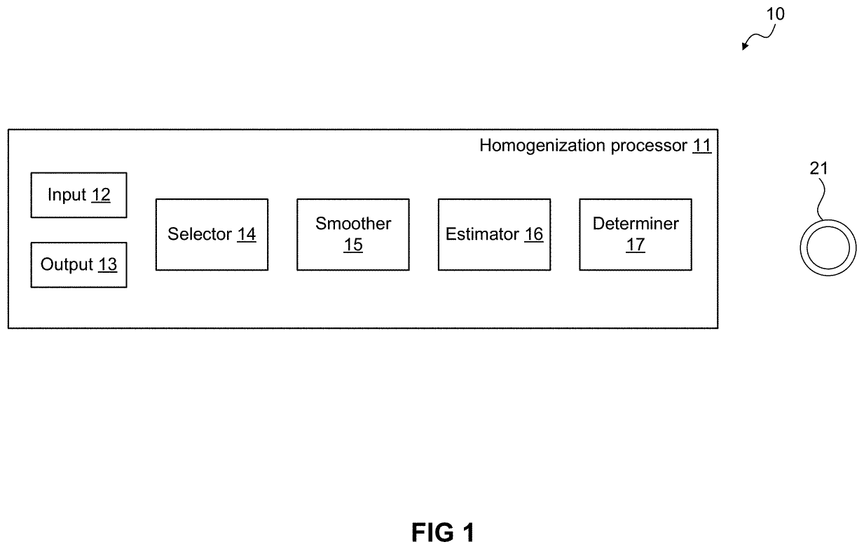

FIG. 1 shows a schematic view of an image processing system (image processor) 10 for performing a method according to the disclosure. The image processing system 10 comprises a homogenization unit (homogenization processor) 11 having an input 12, an output 13, a selection unit (selector) 14, a smoothing unit (smoother) 15, an estimation unit (estimator) 16, and a determination unit (determiner) 17. In an exemplary embodiment, the homogenization unit 11 includes processing circuitry that is configured to perform one or more functions and/or operations of the homogenization unit 11, including generating a homogenization field for image data. Additionally or alternatively, one or more components of the homogenization unit 11 includes processing circuitry configured to perform the functions and/or operations of the respective component(s).

The homogenization unit 11 is furthermore configured for performing a method for generating a homogenization field for image data. For this purpose, in an exemplary embodiment, the homogenization unit 11 comprises computer programs and/or software which can be loaded directly into a memory unit (not shown in further detail) of the homogenization unit 11 and which have program means for performing a method for generating a homogenization field for image data when the computer programs and/or software are/is executed in the homogenization unit 11. To that end, the homogenization unit 11 comprises a processor (not shown in further detail) which is configured to execute the computer programs and/or software. Alternatively hereto, the computer programs and/or software may also be stored on an electronically readable data medium 21 embodied separately from the image processing system 10 and/or homogenization unit 11, in which case a data access by the homogenization unit 11 to the electronically readable data medium 21 can be performed via a data network.

A method for generating a homogenization field for image data may also be present in the form of a computer program product which implements the method on the homogenization unit 11 when it is executed on the homogenization unit 11. Similarly, an electronically readable data medium 21 having electronically readable control information stored thereon may be present, said control information comprising at least one such computer program product as just described and being embodied in such a way that it performs the described method when the data medium 21 is used in a homogenization unit 11 of an image processing system 10.

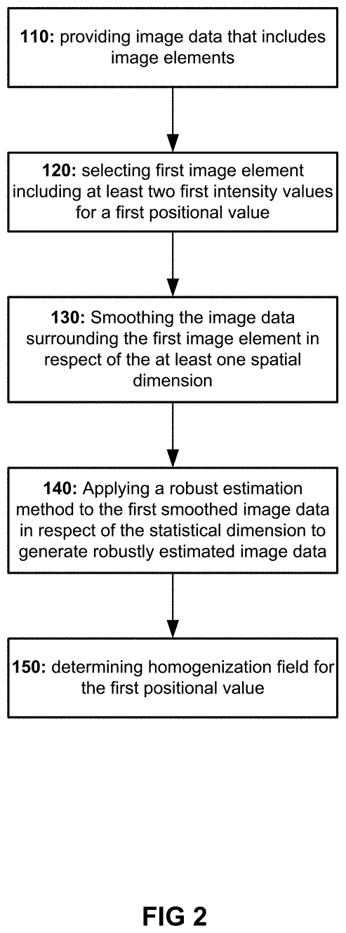

FIG. 2 shows a flowchart of a first embodiment of an inventive method for generating a homogenization field. The image data comprising a plurality of image elements is provided in method step 110. A first image element comprising at least two first intensity values for a first positional value is selected in method step 120. The image data surrounding the first image element in respect of the at least one spatial dimension is smoothed in method step 130. In method step 140, robustly estimated image data is generated by application of a robust estimation method to the first smoothed image data in respect of the statistical dimension. This may comprise a forming of a quantile for the at least two first intensity values. The homogenization field for the first positional value is determined in method step 150 taking into account the robustly estimated image data. In this case, a rule for a combination of the image data in the statistical dimension may be optionally taken into account. The homogenization field can indicate a proportion of corrupted image data in the image data, in particular a proportion of corrupted intensity values in the statistical dimension. In an exemplary embodiment, method steps 120, 130, 140 and 150 are repeated for all image elements encompassed by the image data.

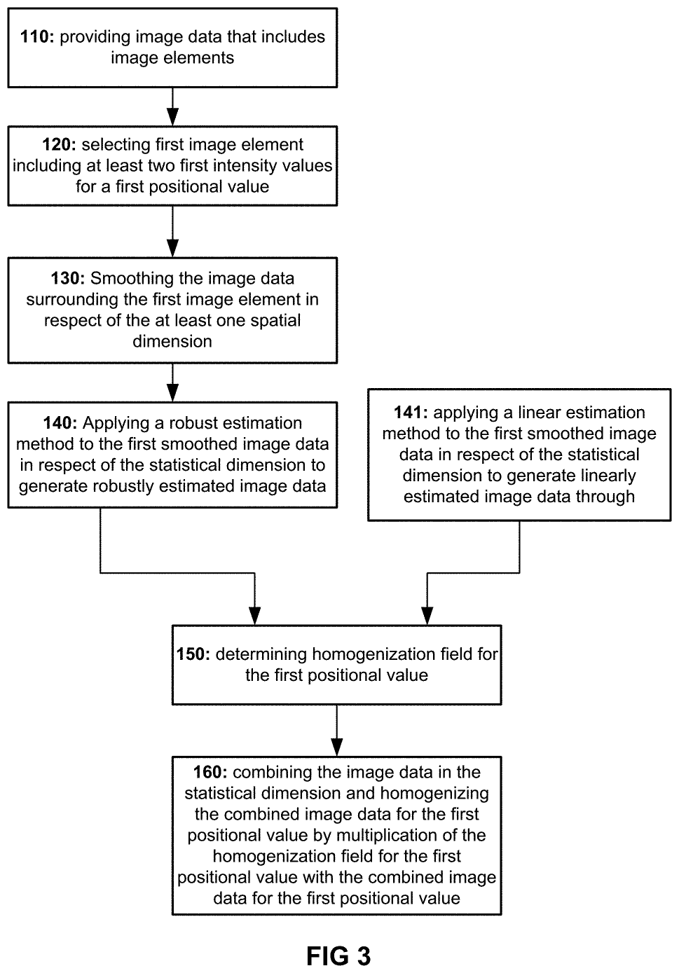

FIG. 3 shows a flowchart of a second embodiment of an inventive method for generating a homogenization field. It differs from the first embodiment illustrated in FIG. 2 by optional method steps which may be combined with one another or which in each case may individually constitute an extension of the method described in FIG. 2.

Method step 141 provides a generation of linearly estimated image data through application of a linear estimation method to the first smoothed image data in respect of the statistical dimension. The linear estimation method may comprise a forming of an arithmetic mean value over the at least two intensity values. The image data linearly estimated in such a way is taken into account in the determination of the homogenization field in method step 150. Determining the homogenization field may thus comprise a ratio of the robustly estimated image data to the linearly estimated image data.

Method step 160 comprises a combination of the image data in the statistical dimension into combined image data and a homogenization of the combined image data for the first positional value by multiplication of the homogenization field for the first positional value with the combined image data for the first positional value.

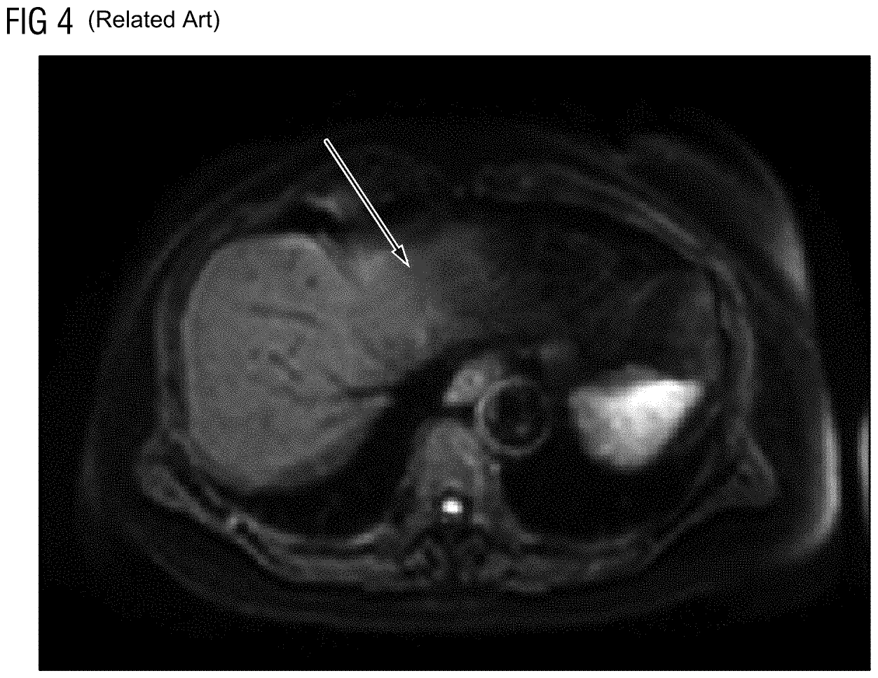

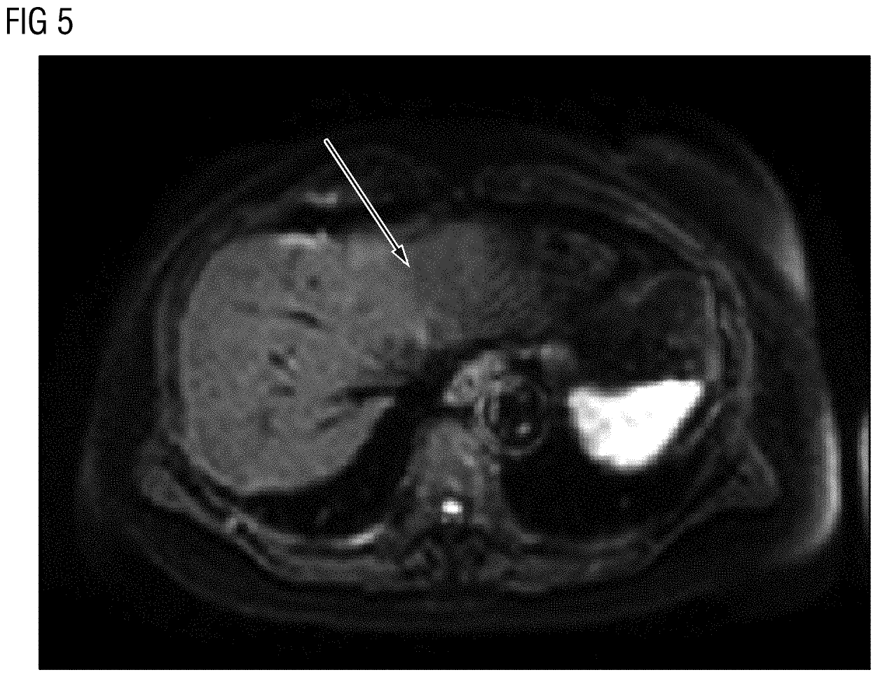

FIG. 4 shows conventionally homogenized diffusion-weighted image data. FIG. 5 shows the same diffusion-weighted image data, though homogenized using an inventively generated homogenization field according to one or more of the exemplary embodiments of the disclosure. It can be seen in this case that the signal extinctions have been eliminated in FIG. 5 in comparison with FIG. 4 in the region marked by arrows, which is achieved by a more balanced weighting of the intensity values in the statistical dimension brought about by means of the inventively generated homogenization field.

Although the disclosure has been illustrated and described in greater detail on the basis of the exemplary embodiments, the disclosure is not limited by the disclosed examples and other variations may be derived herefrom by the person skilled in the art without leaving the scope of protection of the disclosure.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for generating a homogenization field for image data, comprising:
providing the image data that includes a plurality of image elements imaging an examination region of an examination subject, the examination region being defined by positional values in at least one spatial dimension, wherein one image element in each case from the plurality of image elements for one positional value in each case in the spatial dimension includes at least two intensity values in a statistical dimension;
selecting, from the plurality of image elements, a first image element comprising at least two first intensity values for a first positional value;
smoothing image data surrounding the first image element in respect of the at least one spatial dimension to generate first smoothed image data;
applying a robust estimation method to the first smoothed image data in respect of the statistical dimension to generate robustly estimated image data; and
determining the homogenization field for the first positional value based on the robustly estimated image data.

2. The method as claimed in claim 1, wherein the homogenization field is determined based on a combination of the image data in the statistical dimension.

3. The method as claimed in claim 1, further comprising:
combining the image data in the statistical dimension to generate combined image data; and
homogenizing the combined image data for the first positional value based on the homogenization field for the first positional value and the combined image data for the first positional value.

4. The method as claimed in claim 3, wherein the homogenizing the combined image data for the first positional value comprises multiplying the homogenization field for the first positional value with the combined image data for the first positional value.

5. The method as claimed in claim 1, wherein the robust estimation method comprises a forming of an empirical p-quantile.

6. The method as claimed in claim 1, wherein the robust estimation method applied to the first smoothed image data comprises: determining a proportion of corrupted intensity values in the at least two first intensity values in the statistical dimension based on the first smoothed image data surrounding the first positional value.

7. The method as claimed in claim 1, further comprising: applying a linear estimation method to the first smoothed image data in respect of the statistical dimension to generate linearly estimated image data, wherein the homogenization field for the first positional value is determined based on the linearly estimated image data.

8. The method as claimed in claim 7, wherein the determination of the homogenization field for the first positional value is based on a ratio of the robustly estimated image data to the linearly estimated image data.

9. The method as claimed in claim 7, wherein the robustly estimated image data and/or the linearly estimated image data are modified by a regularizer.

10. The method as claimed in claim 7, wherein the linear estimation method comprises forming an arithmetic mean and/or a standard deviation.

11. The method as claimed in claim 8, wherein the linear estimation method comprises forming an arithmetic mean and/or a standard deviation.

12. The method as claimed in claim 1, wherein the image data is diffusion-weighted image data and the image data in the statistical dimension is at least partially different based on its diffusion direction.

13. The method as claimed in claim 1, wherein the smoothing of the image data comprises performing a convolution of the image data.

14. A computer program product which comprises a program and is loadable into a memory of a programmable homogenization processor, when executed by the homogenization processor, causes the homogenization processor to perform the method for generating a homogenization field as claimed in claim 1.

15. A non-transitory computer-readable storage medium with an executable program stored thereon, that when executed, instructs a processor to perform the method of claim 1.

16. An image processing system operable to generate a homogenization field, comprising:
an interface configured to receive image data that includes a plurality of image elements imaging an examination region of an examination subject, the examination region being defined by positional values in at least one spatial dimension, wherein one image element in each case from the plurality of image elements for one positional value in each case in the spatial dimension includes at least two intensity values in a statistical dimension; and
a homogenization processor that is configured to:
select, from the plurality of image elements, a first image element comprising at least two first intensity values for a first positional value;
smooth image data surrounding the first image element in respect of the at least one spatial dimension to generate first smoothed image data;
apply a robust estimation method to the first smoothed image data in respect of the statistical dimension to generate robustly estimated image data; and
determine the homogenization field for the first positional value based on the robustly estimated image data.
